(19) United States
(12) Patent Application Publication
(10) Pub. No.: US 2024/0304427 A1
(43) Pub. Date: Sep. 12, 2024

(54) INTERNAL PRESSURE CONTROL APPARATUS AND SUBSTRATE PROCESSING APPARATUS INCLUDING THE SAME

(71) Applicant: Samsung Electronics Co., Ltd., Suwon-si (KR)

(72) Inventors: Sang Ki NAM, Suwon-si (KR); Tae-Hyun KIM, Suwon-si (KR); Sung Ho JANG, Suwon-si (KR); Seul Gi LEE, Suwon-si (KR)

(73) Assignee: Samsung Electronics Co., Ltd., Suwon-si (KR)

(21) Appl. No.: 18/538,419

(22) Filed: Dec. 13, 2023

(30) Foreign Application Priority Data
Mar. 8, 2023 (KR) 10-2023-0030412

(51) Int. Cl. H01J 37/32; H01L 21/67

(52) U.S. Cl. CPC H01J 37/32834; H01J 37/32449; H01J 37/32642; H01L 21/67069; H01J 2237/3341

(57) ABSTRACT

The present disclosure relates to an internal pressure control apparatus capable of uniformly processing an upper surface of a semiconductor substrate and a substrate processing apparatus including the same. The substrate processing apparatus comprising a chamber housing including an exhaust hole for exhausting a process gas flowing thereinto, a substrate support unit inside the chamber housing, supporting a semiconductor substrate, a process gas supply unit providing the process gas to the inside of the chamber housing, a plasma generating unit generating plasma inside the chamber housing by using the process gas, and a ring body installed around the substrate support unit and provided as one body, and further comprising an internal pressure control apparatus controlling an internal pressure of the chamber housing, wherein the internal pressure control apparatus controls a posture of the ring body to control an exhaust amount of the process gas flowing into the chamber housing.

### CROSS-REFERENCE TO RELATED APPLICATION

This application claims priority from Korean Patent Application No. 10-2023-0030412 filed on Mar. 8, 2023, in the Korean Intellectual Property Office and all the benefits accruing therefrom under 35 U.S.C. 119, the contents of which in its entirety are herein incorporated by reference.

### BACKGROUND

### Technical Field

The present disclosure relates to internal pressure control apparatuses for controlling an internal pressure of a substrate processing apparatus processing a semiconductor substrate, and substrate processing apparatuses including the same.

### Description of the Related Art

As the generation of flash memory products such as V-NAND is evolved to increase the number of stacking stages, a defect problem occurs due to an etch rate (E/R) difference between respective areas of a semiconductor substrate. This problem is due to the E/R difference between the respective areas divided into an east-west direction and a north-south direction as well as a radius area divided into a center area, a middle area and an edge area.

### BRIEF SUMMARY

Objects of the present disclosure are to provide internal pressure control apparatuses capable of uniformly processing an upper surface of a semiconductor substrate and substrate processing apparatuses including the same.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to some aspects of the present disclosure, a substrate processing apparatus including a chamber housing an exhaust hole for exhausting a process gas flowing thereinto; a substrate support unit disposed inside the chamber housing, supporting a semiconductor substrate; a process gas supply unit providing the process gas to the inside of the chamber housing; a plasma generating unit generating plasma inside the chamber housing by using the process gas; and a ring body installed around the substrate support unit and provided as one body, and further including an internal pressure control apparatus controlling an internal pressure of the chamber housing, wherein the internal pressure control apparatus controls a posture of the ring body to control an exhaust amount of the process gas flowing into the chamber housing.

According to some aspects of the present disclosure, an internal pressure control apparatus installed in a facility for processing a semiconductor substrate by using plasma, the internal pressure control apparatus including a ring body installed around a substrate support unit supporting the semiconductor substrate and provided as one body; a first driving unit connected to one side of the ring body through a first connection member; and a second driving unit connected to the other side of the ring body through a second connection member, wherein the internal pressure control apparatus controls a pressure of a space, in which the semiconductor substrate is processed, by controlling a posture of the ring body.

According to some aspects of the present disclosure, a substrate processing apparatus including a chamber housing including an exhaust hole for exhausting a process gas flowing thereinto; a substrate support unit inside the chamber housing, supporting a semiconductor substrate; a process gas supply unit providing the process gas to the inside of the chamber housing; a plasma generating unit generating plasma inside the chamber housing by using the process gas; and an internal pressure control apparatus controlling an internal pressure of the chamber housing, the internal pressure control apparatus including a ring body installed around the substrate support unit and provided as one body; a first driving unit connected to one side of the ring body through a first connection member; and a second driving unit connected to the other side of the ring body through a second connection member, and the internal pressure control apparatus controls a posture of the ring body by tilting the ring body and controls an exhaust amount of a process gas flowing into the chamber housing, the internal pressure control apparatus controls the internal pressure of the chamber housing in accordance with a process time for the semiconductor substrate, the process time including a plurality of cycles, uniformly controls the internal pressure of the chamber housing for each cycle, and controls the internal pressure of the chamber housing by changing the internal pressure of the chamber housing between two different cycles, and the first driving unit and the second driving unit independently control the ring body.

### BRIEF DESCRIPTION OF THE DRAWINGS

These and/or other aspects will become apparent and more readily appreciated from the following description of the embodiments, taken in conjunction with the accompanying drawings in which:

FIG. 1 is a first example view schematically illustrating an internal structure of a semiconductor manufacturing facility for processing a semiconductor substrate according to some example embodiments.

FIG. 2 is a second example view schematically illustrating an internal structure of a semiconductor manufacturing facility for processing a semiconductor substrate according to some example embodiments.

FIG. 3 is a third example view schematically illustrating an internal structure of a semiconductor manufacturing facility for processing a semiconductor substrate according to some example embodiments.

FIG. 4 is a first example view illustrating an internal structure of a substrate processing apparatus constituting a semiconductor manufacturing facility as a cross-sectional view according to some example embodiments.

FIG. 5 is a second example view illustrating an internal structure of a substrate processing apparatus constituting a semiconductor manufacturing facility as a cross-sectional view according to some example embodiments.

FIG. 6 is a third example view illustrating an internal structure of a substrate processing apparatus constituting a semiconductor manufacturing facility as a cross-sectional view according to some example embodiments.

FIG. 7 is a first example view illustrating components of an internal pressure control apparatus applied to a substrate processing apparatus according to some example embodiments.

FIG. 8 is an example view illustrating that a ring body of an internal pressure control apparatus is applied to a substrate processing apparatus according to some example embodiments.

FIG. 9 is a first example view illustrating a shape of the ring body constituting an internal pressure control apparatus according to some example embodiments.

FIG. 10 is a second example view illustrating a shape of a ring body constituting an internal pressure control apparatus according to some example embodiments.

FIG. 11 is a third example view illustrating a shape of a ring body constituting an internal pressure control apparatus according to some example embodiments.

FIG. 12 is a first example view illustrating an arrangement of a ring body constituting an internal pressure control apparatus according to some example embodiments.

FIG. 13 is a second example view illustrating an arrangement of a ring body constituting an internal pressure control apparatus according to some example embodiments.

FIG. 14 is a first example view illustrating a ring body control method of a driving unit constituting an internal pressure control apparatus according to some example embodiments.

FIG. 15 is a second example view illustrating a ring body control method of a driving unit constituting an internal pressure control apparatus according to some example embodiments.

FIG. 16 is a first example view illustrating a movement change of a ring body under the control of a driving unit according to some example embodiments.

FIG. 17 is a second example view illustrating a movement change of a ring body under the control of a driving unit according to some example embodiments.

FIG. 18 is a third example view illustrating a movement change of a ring body under the control of a driving unit according to some example embodiments.

FIG. 19 is a fourth example view illustrating a movement change of a ring body under the control of a driving unit according to some example embodiments.

FIG. 20 is a third example view illustrating a ring body control method of a driving unit constituting an internal pressure control apparatus according to some example embodiments.

FIG. 21 is a fourth example view illustrating a ring body control method of a driving unit constituting an internal pressure control apparatus according to some example embodiments.

FIG. 22 is a second example view illustrating components of an internal pressure control apparatus applied to a substrate processing apparatus according to some example embodiments.

FIG. 23 is a third example view illustrating components of an internal pressure control apparatus applied to a substrate processing apparatus according to some example embodiments.

FIG. 24 is an example view illustrating an installation form in a substrate processing apparatus of an internal pressure control apparatus according to some example embodiments.

FIG. 25 is a fourth example view illustrating components of an internal pressure control apparatus applied to a substrate processing apparatus according to some example embodiments.

FIG. 26 is a fifth example view illustrating components of an internal pressure control apparatus applied to a substrate processing apparatus according to some example embodiments.

### DETAILED DESCRIPTION OF THE DISCLOSURE

Hereinafter, example embodiments of the present disclosure will be described in detail with reference to the accompanying drawings. The same components in the drawings will be denoted by the same reference numerals, and an overlapping description thereof will be omitted.

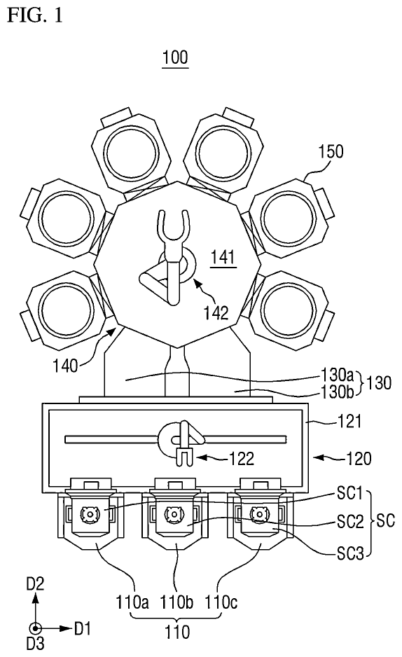

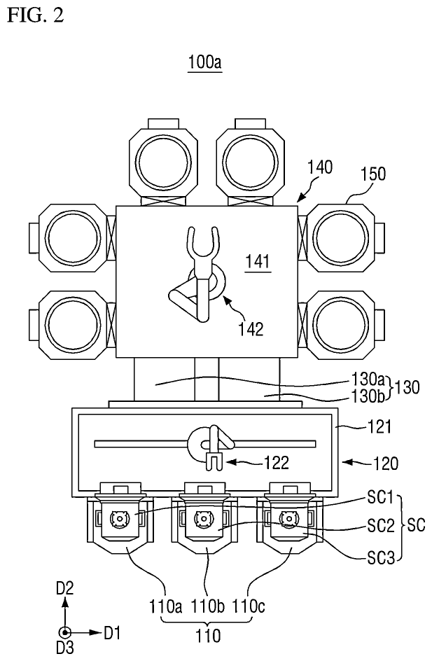

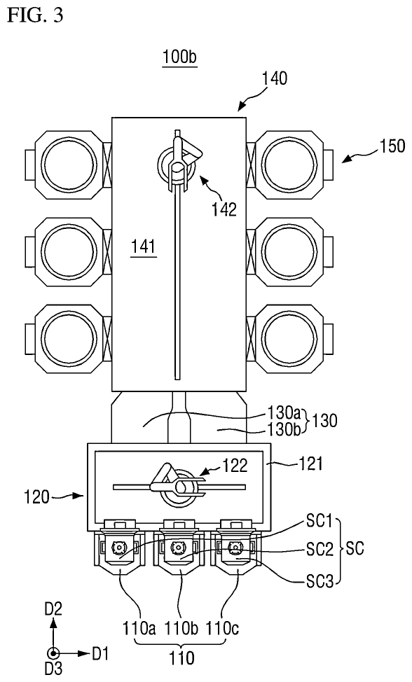

FIG. 1 is a first example view schematically illustrating an internal structure of a semiconductor manufacturing facility for processing a semiconductor substrate. FIG. 2 is a second example view schematically illustrating an internal structure of a semiconductor manufacturing facility for processing a semiconductor substrate. FIG. 3 is a third example view schematically illustrating an internal structure of a semiconductor manufacturing facility for processing a semiconductor substrate.

Referring to FIGS. 1 to 3, a semiconductor manufacturing facility 100 may include a load port module 110, an index module 120, a load lock chamber 130, a transfer module 140, and a process chamber 150.

The semiconductor manufacturing facility 100 is a system for processing a semiconductor substrate by using an etching process, a cleaning process, a deposition process, and/or the like. The semiconductor manufacturing facility 100 may include one process chamber, but is not limited thereto, and may include a plurality of process chambers. The plurality of process chambers may include homogeneous process chambers, but are not limited thereto, and may include heterogeneous process chambers. When the semiconductor manufacturing facility 100 includes the plurality of process chambers, the semiconductor manufacturing facility 100 may be provided as a multi-chamber type substrate processing system.

The load port module 110 is provided so that a container SC on which a plurality of semiconductor substrates are loaded may be seated. The container SC may be, for example, a front opening unified pod (FOUP) or the like.

In the load port module 110, the container SC may be loaded or unloaded. Also, in the load port module 110, the semiconductor substrate stored in the container SC may be loaded or unloaded.

When a loading or unloading target is the container SC, a container transport apparatus may load or unload the container SC on the load port module 110. In detail, the container transport apparatus may load the container SC on the load port module 110 by seating the container SC gripped by the container transport apparatus on the load port module 110. In addition, the container transport apparatus may unload the container SC on the load port module 110 by gripping the container SC seated on the load port module 110. Although not shown in FIGS. 1 to 3, the container transport apparatus may be an overhead hoist transporter (OHT).

When the loading or unloading target is the semiconductor substrate, a first transfer robot 122 may load or unload the semiconductor substrate on the container SC seated on the load port module 110. In case of unloading of the semiconductor substrate, when the container SC is seated on the load port module 110, the first transfer robot 122 may access the load port module 110 and then take the semiconductor substrate out of the container SC. In case of loading of the semiconductor substrate, when processing of the semiconductor substrate is completed in the process chamber 150, the first transfer robot 122 may take the semiconductor substrate out of the load lock chamber 130 and then carry the semiconductor substrate into the container SC.

A plurality of load port modules 110 may be disposed in front of the index module 120. For example, three load port modules 110a, 110b and 110c, such as a first load port module 110a, a second load port module 110b, and a third load port module 110c, may be disposed in front of the index module 120.

When a plurality of load port modules 110 are disposed in front of the index module 120, the container SC seated on each load port module may load different types of objects thereon. For example, when the first load port module 110a, the second load port module 110b and the third load port module 110c are disposed in front of the index module 120, the first container SC1 seated on the first load port module 110a may load a wafer type sensor thereon, and the second container SC2 seated on the second load port module 110b may load the semiconductor substrate, that is, a wafer, thereon, and the third container SC3 seated on the third load port module 110c may load a consumable component, such as a focus ring and an edge ring, thereon.

However, the present disclosure is not limited to the above example. The containers SC seated on the respective load port modules may load the same types of objects thereon. Alternatively, the containers seated on some of the plurality of load port modules may load the same types of objects, and the containers seated on some other several load port modules may load different types of objects thereon.

The index module 120 may be disposed between the load port module 110 and the load lock chamber 130, and may be provided as an interface so that the semiconductor substrate may be transported between the load lock chamber 130 and the container SC on the load port module 110.

The index module 120 may include a first module housing 121 and a first transfer robot 122. The first transfer robot 122 may be disposed inside the first module housing 121, and may transfer the semiconductor substrate between the load port module 110 and the load lock chamber 130. An internal environment of the first module housing 121 is provided as an atmospheric pressure environment, and the first transfer robot 122 may operate in the atmospheric pressure environment. An atmospheric pressure environment may refer to a pressure environment equalized or substantially equalized to a pressure environment outside of the semiconductor manufacturing facility 100, or, for example, a standard pressure, such as 100 kPa. Only one first transfer robot 122 may be provided in the first module housing 121, but the present disclosure is not limited thereto, and a plurality of first transfer robots 122 may be provided.

Although not shown in FIGS. 1 to 3, the index module 120 may include a buffer chamber. The buffer chamber may temporarily store an unprocessed substrate before returning the unprocessed substrate to the load lock chamber 130. In addition, the buffer chamber may temporarily store the processed substrate before returning the processed substrate to the container SC on the load port module 110. The buffer chamber may be provided on the other sidewall except a sidewall adjacent to the load port module 110 or the load lock chamber 130, but is not limited thereto, and may be provided on the sidewall adjacent to the load port module 110. Alternatively, the buffer chamber may be provided on the sidewall adjacent to the load lock chamber 130.

In some example embodiments, a front end module FEM may be provided on one side of the load lock chamber 130 based on the load lock chamber 130. The front end module FEM may include a load port module 110 and an index module 120, and may be provided, for example, as an equipment front end module (EFEM).

As described above, a plurality of load port modules 110 may be provided in the semiconductor manufacturing facility 100. Referring to the example of FIGS. 1 to 3, the plurality of load port modules may have a structure in which they are arranged in a horizontal direction (first direction D1), but the present disclosure is not limited thereto, and the plurality of load port modules may have a structure in which they are stacked in a vertical direction (third direction D3). When the plurality of load port modules are stacked in the vertical direction, the front end module may be provided as a vertically stacked EFEM.

The load lock chamber 130 may serve as a buffer chamber between an input port and an output port in the semiconductor manufacturing facility 100. That is, the load lock chamber 130 may serve to temporarily store the unprocessed substrate or the processed substrate between the load port module 110 and the process chamber 150. Although not shown in FIGS. 1 to 3, the load lock chamber 130 may include a buffer stage for temporarily storing the semiconductor substrate therein.

A plurality of load lock chambers 130 may be disposed between the index module 120 and the transfer module 140. For example, two load lock chambers 130a and 130b, such as a first load lock chamber 130a and a second load lock chamber 130b, may be disposed between the index module 120 and the transfer module 140.

The plurality of load lock chambers may be disposed in the same direction as an arrangement direction of the plurality of load port modules. Referring to the example of FIGS. 1 to 3, the first load lock chamber 130a and the second load lock chamber 130b may be disposed between the index module 120 and the transfer module 140 in the same direction as the arrangement direction of the three load port modules 110a, 110b and 110c, that is, in the horizontal direction (the first direction D1). The first load lock chamber 130a and the second load lock chamber 130b may be provided in a symmetric single-layered structure in which they are spaced apart from each other in the horizontal direction.

However, the present disclosure is not limited to the above example. The plurality of load lock chambers may be disposed in a direction different from the arrangement direction of the plurality of load port modules. The first load lock chamber 130a and the second load lock chamber 130b may be disposed in a direction different from the arrangement direction of the three load port modules 110a, 110b and 110c, that is, in the vertical direction (third direction D3) between the index module 120 and the transfer module 140. The first load lock chamber 130a and the second load lock chamber 130b may be provided in a double layered structure in which they are spaced apart from each other in the vertical direction.

Any one of the first load lock chamber 130a and the second load lock chamber 130b may temporarily store the semiconductor substrate, that is, the unprocessed substrate, which is transferred from the index module 120 to the transfer module 140. The other load lock chamber may temporarily store the semiconductor substrate transferred from the transfer module 140 to the index module 120, that is, the processed substrate. However, the present disclosure is not limited to the above example, and the first load lock chamber 130a and the second load lock chamber 130b may commonly serve to temporarily store the unprocessed substrate and the processed substrate.

The load lock chamber 130 may change its inside to any one of a vacuum environment and an atmospheric pressure environment by using a gate valve or the like. A vacuum environment may refer to an environment in which all or nearly all gaseous matter has been removed before processing, as may be understood by one of ordinary skill in the art. In detail, when the first transfer robot 122 of the index module 120 loads the semiconductor substrate to the load lock chamber 130 or the first transfer robot 122 unloads the semiconductor substrate from the load lock chamber 130, the load lock chamber 130 may form its inside in the same or similar environment as or to an internal environment of the index module 120. In addition, when the second transfer robot 142 of the transfer module 140 loads the semiconductor substrate to the load lock chamber 130 or the second transfer robot 142 unloads the semiconductor substrate from the load lock chamber 130, the load lock chamber 130 may form its inside in the same or similar environment as or to an internal environment of the transfer module 140. As a result, the load lock chamber 130 may prevent or reduce an internal atmospheric pressure state of the index module 120 or an internal atmospheric pressure state of the transfer module 140 from being changed.

The transfer module 140 may be disposed between the load lock chamber 130 and the process chamber 150, and may be provided as an interface so that the semiconductor substrate may be transferred between the load lock chamber 130 and the process chamber 150.

The transfer module 140 may include a second module housing 141 and a second transfer robot 142. The second transfer robot 142 may be disposed inside the second module housing 141, and may transfer the semiconductor substrate between the load lock chamber 130 and the process chamber 150. An internal environment of the second module housing 141 is provided as a vacuum environment, and the second transfer robot 142 may operate in the vacuum environment. Only one second transfer robot 142 may be provided in the second module housing 141, but the present disclosure is not limited thereto, and a plurality of second transfer robots 142 may be provided.

The transfer module 140 may be connected to a plurality of process chambers. The second module housing 141 may include a plurality of sides, and the second transfer robot 142 may be freely rotated through each side of the second module housing 141 so that the semiconductor substrate may be loaded into the plurality of process chambers or unloaded from the plurality of process chambers.

The process chamber 150 serves to process the semiconductor substrate. When the unprocessed semiconductor substrate is provided, the process chamber 150 may process the semiconductor substrate and provide the processed semiconductor substrate to the load lock chamber 130 through the transfer module 140. The process chamber 150 will be described later in more detail.

When the semiconductor manufacturing facility 100 includes a plurality of process chambers, the semiconductor manufacturing facility 100 may be formed in a structure having a cluster platform. For example, the plurality of process chambers may be disposed in a cluster manner based on the transfer module 140 as shown in the example of FIG. 1, but the present disclosure is not limited thereto. When the semiconductor manufacturing facility 100 includes a plurality of process chambers, the semiconductor manufacturing facility 100 may be formed in a structure having a quad platform. For example, the plurality of process chambers may be disposed in a quad manner based on the transfer module 140 as shown in the example embodiments of the semiconductor manufacturing facility 100a of FIG. 2. Alternatively, when the semiconductor manufacturing facility 100 includes a plurality of process chambers, the semiconductor manufacturing facility 100 may be formed in a structure having an in-line platform. For example, as shown in the example embodiments of the semiconductor manufacturing facility 100b of FIG. 3, the plurality of process chambers may be disposed in an in-line manner based on the transfer module 140, and two different process chambers may be disposed in series at both sides of the transfer module 140.

Although not shown in FIGS. 1 to 3, the semiconductor manufacturing facility 100 may further include a control device. The control device serves to control the overall operation of each module constituting the semiconductor manufacturing facility 100. For example, the control device may control transfer of the semiconductor substrate of the first transfer robot 122 or the second transfer robot 142, may control a change in an internal environment of the load lock chamber 130, and may control a substrate processing process of the process chamber 150.

The control device may include a process controller consisting of a microprocessor or a microcomputer for controlling the semiconductor manufacturing facility 100, a keyboard for a command input operations to allow an operator to manage the semiconductor manufacturing facility 100, an user interface consisting of a display for visualizing and displaying an operation situation of the semiconductor manufacturing facility 100, a control program for executing various processes executed in the semiconductor manufacturing facility 100 under the control of the process controller, a program for executing processing on each module in accordance with various data and processing conditions, and a storage for storing a processing recipe. The user interface and the storage may be connected to the process controller. The processing recipe may be stored in a storage medium of the storage, and the storage medium may be a hard disk, a portable disk such as a CD-ROM or a DVD, or a semiconductor memory such as a flash memory.

Next, the process chamber 150 will be described. A surface of the process chamber 150 may be made of Alumite on which a cathode oxide film is formed, and the inside of the process chamber 150 may be configured to be airtight. A plurality of process chambers may be provided in the semiconductor manufacturing facility 100, and the plurality of process chambers may be disposed to be spaced apart from each other around the transfer module 140, but the present disclosure is not limited thereto. A single process chamber may be provided in the semiconductor manufacturing facility 100. The process chamber 150 may be provided in a cylindrical shape, but is not limited thereto, and may be provided in a shape other than the cylindrical shape.

Although described above, the process chamber 150 may process the semiconductor substrate. Hereinafter, an internal structure of the process chamber 150 will be described by defining the process chamber 150 as a substrate processing apparatus.

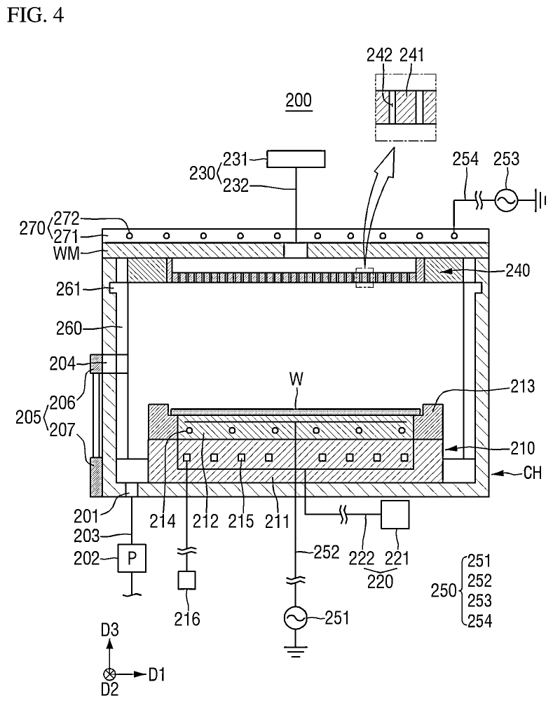

FIG. 4 is a first example view illustrating an internal structure of a substrate processing apparatus constituting a semiconductor manufacturing facility as a cross-sectional view. Referring to FIG. 4, the substrate processing apparatus 200 may include a chamber housing CH, a substrate support unit 210, a cleaning gas supply unit 220, a process gas supply unit 230, a showerhead unit 240, a plasma generating unit 250, a liner unit 260, a window module WM, and an antenna unit 270.

The substrate processing apparatus 200 may process a semiconductor substrate W by using plasma. The substrate processing apparatus 200 may process the semiconductor substrate W by a dry method. The substrate processing apparatus 200 may process the semiconductor substrate W, for example, in a vacuum environment. The substrate processing apparatus 200 may process the semiconductor substrate W by using an etching process, but the present disclosure is not limited thereto, and the substrate processing apparatus 200 may process the semiconductor substrate W by using a deposition process or a cleaning process.

The chamber housing CH provides a space for a process of processing the semiconductor substrate W by using plasma, that is, a plasma process. The chamber housing CH may have an exhaust hole 201 therebelow.

The exhaust hole 201 may be connected to an exhaust line 203 on which a pump 202 is mounted. The exhaust hole 201 may discharge reaction by-products generated during the plasma process and gas remaining inside the chamber housing CH to the outside of the chamber housing CH through the exhaust line 203. In this case, an inner space of the chamber housing CH may be decompressed.

An opening 204 may be formed by passing through a sidewall of a chamber housing CH. The opening 204 may be provided as a path through which the semiconductor substrate W enters and exits the chamber housing CH. The opening 204 may be configured to be automatically opened and closed by, for example, a door assembly 205.

The door assembly 205 may include an outer door 206 and a door driver 207. The outer door 206 may open and close the opening 204 on an outer wall of the chamber housing CH. The outer door 206 may be moved in a height direction (third direction D3) of the substrate processing apparatus 200 under the control of the door driver 207. The door driver 207 may operate using at least one element selected from a motor, a hydraulic cylinder, and a pneumatic cylinder.

The substrate support unit 210 is installed in an inner lower area of the chamber housing CH. The substrate support unit 210 may adsorb and support the semiconductor substrate W by using an electro static force, but the present disclosure is not limited thereto, and the substrate support unit 210 may support the semiconductor substrate W by using various methods such as vacuum and mechanical clamping.

The substrate support unit 210 may include a base 211 and an electro static chuck (ESC) 212 when supporting the semiconductor substrate W by using the electro static force. The electro static chuck 212 is disposed on the base 211, and may support the semiconductor substrate W seated thereon using the electro static force. The base 211 may be provided, for example, as an aluminum body. The electro static chuck 212 may be formed of, for example, a ceramic material.

The ring assembly 213 is provided to surround an outer edge area of the electro static chuck 212. The ring assembly 213 may serve to concentrate ions on the semiconductor substrate W when a plasma process is performed inside the chamber housing CH. The ring assembly 213 may be formed of silicon. For example, the ring assembly 123 may be provided as a focus ring.

Although not shown in FIG. 4, the substrate processing apparatus 200 may further include an edge ring provided to surround an outer area of the ring assembly 213. The edge ring may serve to prevent or reduce a side of the electro static chuck 212 from being damaged by the plasma. The edge ring may be formed of an insulator material such as Quartz.

A heating member 214 and a cooling member 215 are provided to maintain the semiconductor substrate W at a process temperature when the substrate processing process is performed inside the chamber housing CH. The heating member 214 may be provided as a heat wire in order to increase a temperature of the semiconductor substrate W. For example, the heating member 214 may be installed inside the electro static chuck 212. The cooling member 215 may be provided as a cooling line through which a refrigerant flows to lower the temperature of the semiconductor substrate W. For example, the cooling member 215 may be installed inside the base 211. The cooling member 215 may be supplied with a refrigerant using a chiller 216.

The cleaning gas supply unit 220 provides a cleaning gas to the electro static chuck 212 or the ring assembly 213 to remove particles remaining in the electro static chuck 212 or the ring assembly 213. For example, the cleaning gas supply unit 220 may provide a nitrogen gas (N₂ Gas) as a cleaning gas.

The cleaning gas supply unit 220 may include a cleaning gas supply source 221 and a cleaning gas supply line 222. The cleaning gas supply line 222 may be connected to a space between the electro static chuck 212 and the ring assembly 213. The cleaning gas supplied by the cleaning gas supply source 221 may move to a space between the electro static chuck 212 and the ring assembly 213 through the cleaning gas supply line 222 to remove particles remaining on an edge portion of the electro static chuck 212 or an upper portion of the ring assembly 213.

The process gas supply unit 230 provides a process gas to the inner space of the chamber housing CH. The process gas supply unit 230 may provide a process gas to the inner space of the chamber housing CH through an upper cover of the chamber housing CH, that is, a hole formed by passing through the window module WM, but the present disclosure is not limited thereto. The process gas supply unit 230 may provide a process gas to the inner space of the chamber housing CH through a hole formed by passing through the sidewall of the chamber housing CH.

The process gas supply unit 230 may include a process gas supply source 231 and a process gas supply line 232. The process gas supply source 231 may provide a gas used for processing the semiconductor substrate W as a process gas. A single process gas supply source may be provided in the substrate processing apparatus 200, but the present disclosure is not limited thereto, and a plurality of process gas supply sources may be provided. When the plurality of process gas supply sources are provided in the substrate processing apparatus 200, the plurality of process gas sources may provide the same kind of process gas, but the present disclosure is not limited thereto. The plurality of process gas sources may provide different kinds of process gases.

The showerhead unit 240 sprays the process gas provided from the process gas supply source 231 to the entire area of the semiconductor substrate W disposed in the inner space of the chamber housing CH. The showerhead unit 240 may be connected to the process gas supply source 231 through the process gas supply line 232.

The showerhead unit 240 may be disposed in the inner space of the chamber housing CH, and may include a plurality of gas feeding holes 242. The plurality of gas feeding holes 242 may be formed by passing through a surface of a body 241 of the showerhead unit 240 in the vertical direction (third direction D3). The plurality of gas feeding holes 242 may be formed to be spaced apart from each other at constant intervals on the body 241 of the showerhead unit 240. The showerhead unit 240 may uniformly spray the process gas to the entire area of the semiconductor substrate W through the plurality of gas feeding holes 242.

The showerhead unit 240 may be installed to face the electro static chuck 212 in the vertical direction (third direction D3) in the chamber housing CH. The showerhead unit 240 may be provided to have a diameter larger than that of the electro static chuck 212, but the present disclosure is not limited thereto. The showerhead unit 240 may be provided to have the same diameter as that of the electro static chuck 212. The showerhead unit 240 may be formed of a silicon material, but is not limited thereto, and may be formed of a metal material.

Although not shown in FIG. 4, the showerhead unit 240 may be divided into a plurality of units. For example, the showerhead unit 240 may be divided into three units, such as a first unit, a second unit, and a third unit. The first unit may be disposed at a position corresponding to a center zone of the semiconductor substrate W. The second unit may be disposed to surround an outer edge of the first unit. The second unit may be disposed at a position corresponding to a middle zone of the semiconductor substrate W. The third unit may be disposed to surround an outer edge of the second unit. The third unit may be disposed at a position corresponding to an edge zone of the semiconductor substrate W.

Although not shown in FIG. 4, the process gas supply unit 230 may include a process gas distributor and a process gas distribution line to distribute the process gas in each unit of the showerhead unit 240 when the showerhead unit 240 is divided into a plurality of units. The process gas distributor may be installed on the process gas supply line 232, and may distribute the process gas supplied from the process gas supply source 231 to each unit of the showerhead unit 240 through the process gas distribution line. The process gas distribution line may be a portion of the process gas supply line 232, and may connect the process gas distributor with each unit of the showerhead unit 240.

The plasma generating unit 250 generates plasma from gas remaining in a discharge space. In this case, the discharge space is an inner space of the chamber housing CH, and may be a space formed between the showerhead unit 240 and the window module WM. Alternatively, the discharge space may be a space formed between the substrate support unit 210 and the showerhead unit 240. When the discharge space is a space formed between the substrate support unit 210 and the showerhead unit 240, the discharge space may be divided into a plasma area and a process area. The plasma area may be formed to be higher than the process area.

The plasma generating unit 250 may generate plasma in the discharge space by using an inductively coupled plasma (ICP) source. For example, the plasma generating unit 250 may generate plasma in the discharge space by utilizing the electro static chuck 212 as a first electrode (lower electrode) and utilizing the antenna unit 270 as a second electrode (upper electrode).

However, the present disclosure is not limited to the above example. The plasma generating unit 250 may generate plasma in the discharge space by using a capacitively coupled plasma (CCP) source. For example, the plasma generating unit 250 may generate plasma in the discharge space by utilizing the electro static chuck 212 as a first electrode (lower electrode) and utilizing the showerhead unit 240 as a second electrode (upper electrode). The case that the plasma generating unit 250 uses the CCP source will be described later.

The plasma generating unit 250 includes a first high frequency power source 251, a first transmission line 252, a second high frequency power source 253, and a second transmission line 254.

The first high frequency power source 251 applies RF power to the first electrode. The first high frequency power source 251 may serve as a plasma source for generating plasma in the chamber housing CH.

A single first high frequency power source 251 may be provided in the substrate processing apparatus 200, but the present disclosure is not limited thereto, and a plurality of first high frequency power sources may be provided. When the plurality of first high frequency power sources 251 are provided in the substrate processing apparatus 200, the first high frequency power sources 251 may be disposed in parallel on the first transmission line 252.

Although not shown in FIG. 4, when the plurality of first high frequency power sources 251 are provided in the substrate processing apparatus 200, the plasma generating unit 250 may include a first matching network electrically connected to each of the first high frequency power sources. When frequency powers of different sizes are input from the plurality of first high frequency power sources, the first matching network may serve to match the frequency powers and apply them to the first electrode.

The first transmission line 252 connects the first electrode with a GND. The first high frequency power source 251 may be installed on the first transmission line 252.

Although not shown in FIG. 4, a first impedance matching circuit may be provided on the first transmission line 252 connecting the first high frequency power source 251 with the first electrode to achieve impedance matching. The first impedance matching circuit may act as a lossless passive circuit, and may allow electric energy to be transferred, for example, at a high rate or maximally, from the first high frequency power source 251 to the first electrode.

The second high frequency power source 253 applies RF power to the second electrode. The second high frequency power source 253 may serve to control characteristics of plasma in the chamber housing CH. For example, the second high frequency power source 253 may serve to adjust ion bombardment energy inside the chamber housing CH.

A single second high frequency power source may be provided in the substrate processing apparatus 200, but the present disclosure is not limited thereto, and a plurality of second high frequency power sources may be provided. When the plurality of second high frequency power sources are provided in the substrate processing apparatus 200, the second high frequency power sources 253 may be disposed in parallel on the second transmission line 254.

Although not shown in FIG. 4, when a plurality of second high frequency power sources are provided in the substrate processing apparatus 200, the plasma generating unit 250 may include a second matching network electrically connected to the plurality of second high frequency power sources. When frequency powers of different sizes are input from the plurality of second high frequency power sources, the second matching network may serve to match the frequency powers and apply them to the second electrode.

The second transmission line 254 connects the second electrode with the GND. The second high frequency power source 253 may be installed on the second transmission line 254.

Although not shown in FIG. 4, a second impedance matching circuit may be provided on the second transmission line 254 connecting the second high frequency power source 253 with the second electrode to achieve impedance matching. The second impedance matching circuit may act as a lossless passive circuit, and may allow electric energy to be transferred, for example, at a high rate or maximally, from the second high frequency power source 253 to the second electrode.

Meanwhile, in the same manner as the second high frequency power source 253, the first high frequency power source 251 may serve to control characteristics of plasma in the chamber housing CH.

The liner unit (or wall liner) 260 protects the inside of the chamber housing CH from an arc discharge generated in a process of exciting a process gas or impurities generated during the substrate processing process. The liner unit 260 may be formed to cover an inner sidewall of the chamber housing CH.

The liner unit 260 may include a support ring 261 on an upper portion of the body. The support ring 261 may be protruded from an upper portion of the body in an outward direction (first direction D1), and may serve to fix the body to the chamber housing CH.

The window module WM serves as an upper cover of the chamber housing CH to seal the inner space of the chamber housing CH. The window module WM may be provided separately from the chamber housing CH, but is not limited thereto, and may be provided as a portion of the chamber housing CH. When the window module WM is provided separately from the chamber housing CH, the window module WM may cover the opened upper portion of the chamber housing CH. When the window module WM is provided as a portion of the chamber housing CH, the window module WM may be integrally provided with the chamber housing CH.

The window module WM may be formed of a dielectric window by using an insulating material. For example, the window module WM may be formed by using alumina (Al₂O₃). When a plasma process is performed in the inner space of the chamber housing CH, the window module WM may include a coating layer on a surface to suppress generation of particles.

The antenna unit 270 serves to generate a magnetic field and an electric field inside the chamber housing CH to excite the process gas into plasma. The antenna unit 270 may operate using the RF power supplied from the second high frequency power source 253. The antenna unit 270 may be provided on an upper portion of the chamber housing CH. For example, the antenna unit 270 may be provided on the window module WM, but is not limited thereto. The antenna unit 270 may be provided on the sidewall of the chamber housing CH.

The antenna unit 270 may include an antenna 272 inside a body 271 or on a surface of the body 271. The antenna 272 may be provided to form a closed loop by using a coil. The antenna 272 may be formed in a spiral shape or various other shapes along a width direction (the first direction D1) of the chamber housing CH.

The antenna unit 270 may be formed to have a planar type, but is not limited thereto. The antenna unit 270 may be formed to have a cylindrical type. When the antenna unit 270 is formed to have a planar type, the antenna unit 270 may be provided on the upper portion of the chamber housing CH. When the antenna unit 270 is formed to have a cylindrical type, the antenna unit 270 may be provided to surround an outer sidewall of the chamber housing CH.

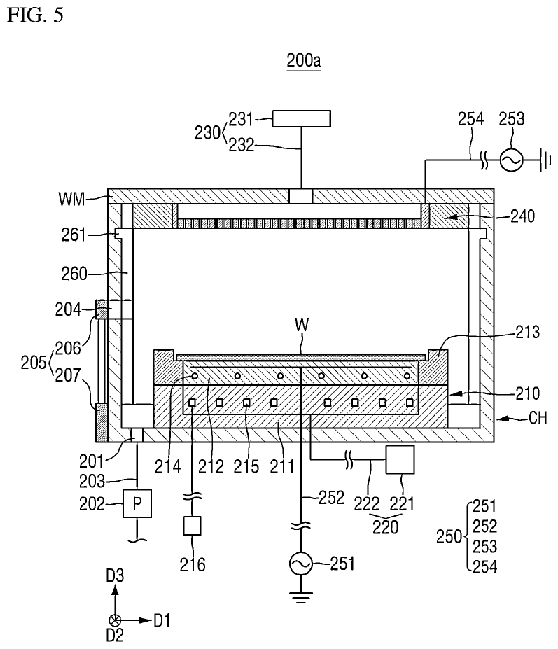

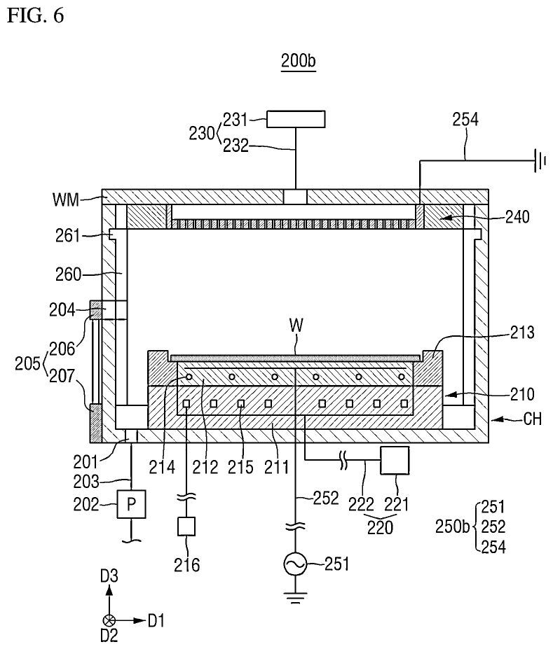

As described above, the case that the plasma generating unit 250 generates plasma in the discharge space by using the ICP source has been described with reference to FIG. 4. Hereinafter, the case that the plasma generating unit 250 generates plasma in the discharge space by using the CCP source will be described with reference to FIGS. 5 and 6. Hereinafter, description of a portion duplicated with the case of FIG. 4 will be omitted, and only a portion corresponding to a difference from the case of FIG. 4 will be described.

FIG. 5 is a second example view illustrating an internal structure of a substrate processing apparatus constituting a semiconductor manufacturing facility as a cross-sectional view. FIG. 6 is a third example view illustrating an internal structure of a substrate processing apparatus constituting a semiconductor manufacturing facility as a cross-sectional view.

Referring to FIGS. 5 and 6, the substrate processing apparatus 200 may include a chamber housing CH, a substrate support unit 210, a cleaning gas supply unit 220, a process gas supply unit 230, a showerhead unit 240, a plasma generating unit 250, a liner unit 260, and a window module WM. That is, the substrate processing apparatus 200 of FIGS. 5 and 6 may not include the antenna unit 270 as compared with the substrate processing apparatus 200 of FIG. 4.

As shown in the example embodiments of the substrate processing apparatus 200a of FIG. 5, the plasma generating unit 250 may include a first high frequency power source 251, a first transmission line 252, a second high frequency power source 253, and a second transmission line 254, but the present disclosure is not limited thereto, and the plasma generating unit 250 may be configured to include a first high frequency power source 251, a first transmission line 252, and a second transmission line 254 as shown in the example embodiments of the substrate processing apparatus 200b of FIG. 6. That is, the plasma generating unit 250b of FIG. 6 may not include the second high frequency power source 253 as compared with the plasma generating unit 250 of FIG. 5.

In case of FIG. 4, the second transmission line 254 may be connected to the antenna 272 of the antenna unit 270. The second high frequency power source 253 may apply RF power to the antenna 272 of the antenna unit 270. In case of FIG. 5, the second transmission line 254 may be connected to the body 241 of the showerhead unit 240. The second high frequency power source 253 may apply the RF power to the body 241 of the showerhead unit 240.

In case of FIG. 5, the second high frequency power source 253 may be installed on the second transmission line 254. In case of FIG. 6, the second high frequency power source 253 may not be installed on the second transmission line 254. When the second high frequency power source 253 is installed on the second transmission line 254, the plasma generating unit 250 may apply a multi-frequency to the substrate processing apparatus 200.

When an etching process is performed for the semiconductor substrate W, the process gas may flow into the inner space of the chamber housing CH through the showerhead unit 240. The process gas may be radially injected toward a center direction of the semiconductor substrate W, and may be radially injected toward an edge direction of the semiconductor substrate W.

The case that the process gas is injected toward the center direction of the semiconductor substrate W may have a longer stay time than the case that the process gas is injected toward the edge direction of the semiconductor substrate W. In this case, the long stay time occurs because the process gas should move from the center of the upper surface of the semiconductor substrate W toward an outward direction. Since the process gas needs to flow to the edge of the semiconductor substrate W so that it may be removed from the inner space of the chamber housing CH, by-products of a high ratio exist in an edge area of the semiconductor substrate W rather than a center area of the semiconductor substrate W.

Also, when the process gas moves from the center of the semiconductor substrate W toward the outward direction, the process gas has a distribution that starts at a low speed near the center and changes at a high speed toward the outside. This leads to chemical non-uniformity for each area of the semiconductor substrate W, such as a center area, a middle area, and an edge area. In order to improve the non-uniformity, a process factor such as a process gas supply amount, a temperature, and RF power may be controlled differently for each area, but when the non-uniformity is excessive, a problem may not be solved by the process factor alone.

Also, in case of a word line cut (WLC) process, a cut direction is formed in an east-west direction (for example, the first direction D1). In the east-west direction, the cut direction and an airflow direction are matched with each other to represent an excessive etch rate (E/R), and in the north-south direction, the cut direction and the airflow direction are orthogonal to each other to represent a low E/R. There is a large difference between E/R in the cast-west direction and E/R in the north-south direction (for example, the second direction D2). In order to solve the above asymmetric problem, an asymmetric process ring may be applied to the substrate processing apparatus 200, but singularity may be easily generated in an asymmetric connection area, and a lot of time and cost may be required for development cycles such as manufacture, improvement and test when mass production of the semiconductor substrate W is applied.

The present disclosure is characterized in that the upper surface of the semiconductor substrate W is uniformly processed in order to solve the problem of chemical non-uniformity, which follows structurally in the center area, the middle area and the edge area, and the problem of asymmetry in each area divided into east-west and north-south directions. This will be described hereinafter with reference to the drawings.

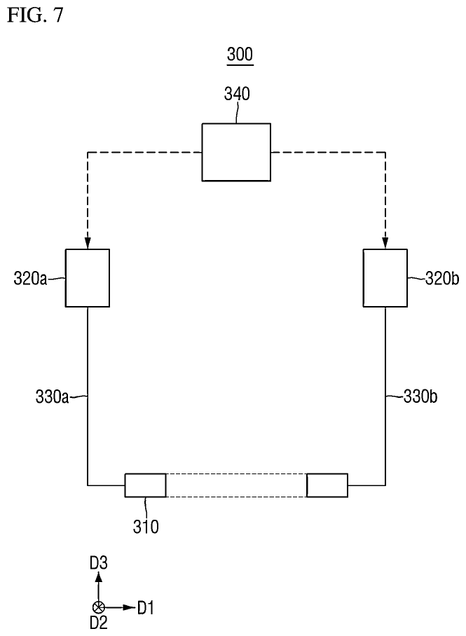

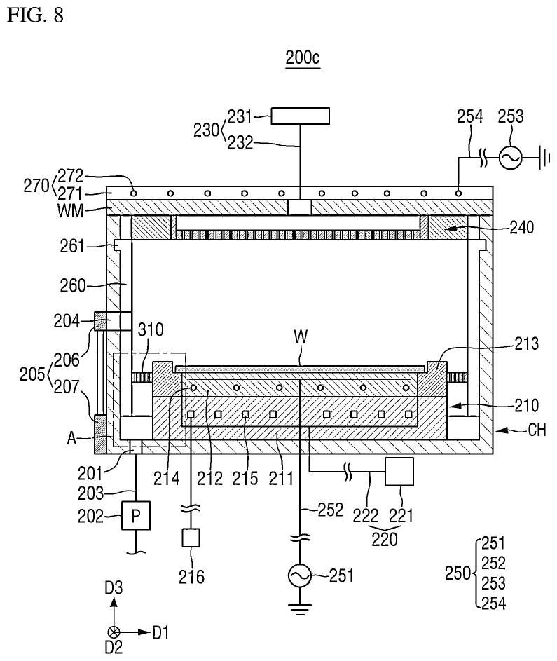

FIG. 7 is a first example view illustrating components of an internal pressure control apparatus applied to a substrate processing apparatus. In addition, FIG. 8 is an example view illustrating that a ring body of an internal pressure control apparatus is applied to a substrate processing apparatus. Referring to FIG. 7, an internal pressure control apparatus 300 may include a ring body 310, a first driving unit 320a, a second driving unit 320b, a first connection member 330a, a second connection member 330b, and a control unit 340.

The internal pressure control apparatus 300 serves to control the internal pressure of the chamber housing CH. The internal pressure control apparatus 300 may control the internal pressure of the chamber housing CH by controlling the amount of the process gas flowing into the inner space of the chamber housing CH. The internal pressure control apparatus 300 may control the amount of the process gas flowing into the inner space of the chamber housing CH by exhausting the process gas in the chamber housing CH to the outside. The internal pressure control apparatus 300 may control the exhaust amount of the process gas flowing into the inner space of the chamber housing CH.

The internal pressure control apparatus 300 may locally control the pressure in a floating chamber structure of the substrate processing apparatus 200 and, at the same time, may control the exhaust amount of the process by-product. The internal pressure control apparatus 300 may serve to restrict plasma distribution in the chamber housing CH.

The ring body 310 serves to exhaust the process gas inside the chamber housing CH to the outside. The ring body 310 may exhaust process by-products or unreacted gas of plasma from the inner space of the chamber housing CH to the outside. As shown in the example embodiments of the substrate processing apparatus 200c of FIG. 8, the ring body 310 may be installed inside the chamber housing CH, and may be installed to be adjacent to the exhaust hole 201.

The ring body 310 may be provided as one body, and may be provided in an annular ring shape. The ring body 310 may be installed to surround the substrate support unit 210. The ring body 310 may be installed to surround the electro static chuck 212, but is not limited thereto, and may be installed to surround the base 211. Also, the ring body 310 may be formed to be in contact with the substrate support unit 210, but is not limited thereto, and may be spaced apart from the substrate support unit 210 so as not to be in contact with the substrate support unit 210.

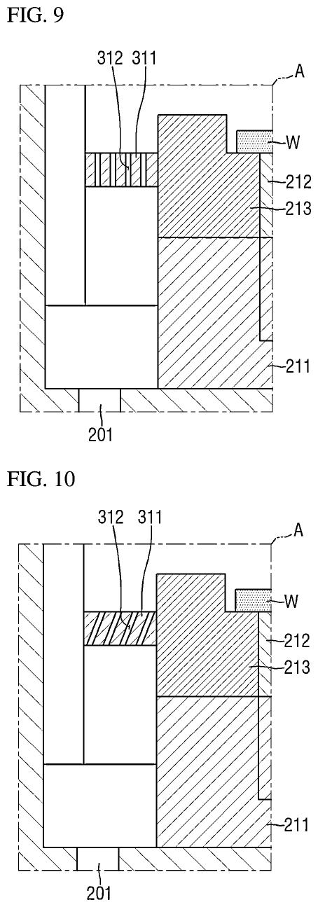

The ring body 310 may include a plurality of slot holes passing through the body to control a flow of the process gas. The plurality of slot holes 312 may be formed in the vertical direction with respect to a longitudinal direction of the body 311 as shown in the example of FIG. 9. When the ring body 310 is disposed in the inner space of the chamber housing CH, the plurality of slot holes 312 may be formed in the vertical direction (the third direction D3) of the chamber housing CH as the longitudinal direction. FIG. 9 is a first example view illustrating a shape of the ring body constituting an internal pressure control apparatus.

However, the present disclosure is not limited to the above example, and the plurality of slot holes 312 may be formed in a direction inclined with respect to the longitudinal direction of the body 311. As shown in the example of FIG. 10, the plurality of slot holes 312 may be formed at an acute angle with respect to the longitudinal direction of the body 311 as its inclination angle. When the ring body 310 is disposed in the inner space of the chamber housing CH, the plurality of slot holes 312 may be formed toward a downward direction outside the chamber housing CH. FIG. 10 is a second example view illustrating a shape of a ring body constituting an internal pressure control apparatus.

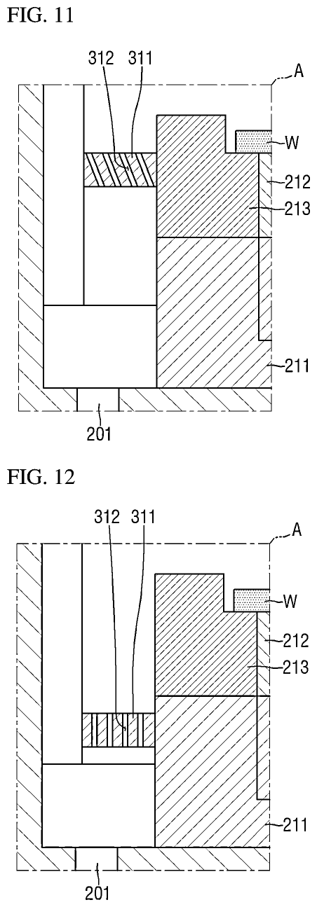

Alternately, as shown in the example of FIG. 11, the plurality of slot holes 312 may be formed at an obtuse angle with respect to the longitudinal direction of the body 311 as its inclination angle. When the ring body 310 is disposed in the inner space of the chamber housing CH, the plurality of slot holes 312 may be formed toward an upward direction outside the chamber housing CH. FIG. 11 is a third example view illustrating a shape of a ring body constituting an internal pressure control apparatus.

The plurality of slot holes 312 may be formed to pass through the body 311 in a state that they are spaced apart from each other. The plurality of slot holes 312 may be spaced apart from each other at constant intervals, but are not limited thereto. The plurality of slot holes 312 may be spaced apart from each other at different intervals. Alternatively, some of the plurality of slot holes 312 may be spaced apart from each other at constant intervals, and some other slot holes 312 may be spaced apart from each other at different intervals.

The plurality of slot holes 312 may have the same diameter/radius, but are not limited thereto. The plurality of slot holes 312 may have different diameters/radiuses. Alternatively, some of the plurality of slot holes 312 may have the same diameter/radius, and some other slot holes 312 may have different diameters/radiuses.

Although described above, the ring body 310 may be installed to surround the electro static chuck 212. In this case, the substrate processing apparatus 200 may include a liner unit 260 installed to be adjacent to the inner sidewall of the chamber housing CH, but may not include the liner unit 260. When the substrate processing apparatus 200 includes the liner unit 260, the ring body 310 may be installed in a space between the ring assembly 213 and the liner unit 260 as shown in the example of FIG. 8, but is not limited thereto. The ring body 310 may be installed in a space between the base 211 and the liner unit 260 as shown in the example of FIG. 12.

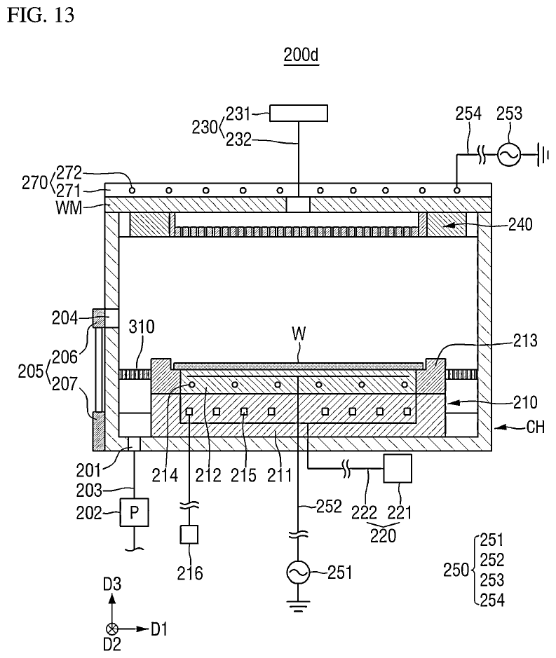

When the substrate processing apparatus 200 does not include the liner unit 260, the ring body 310 may be installed in a space between the ring assembly 213 and the inner sidewall of the chamber housing CH as shown in the example embodiments of the substrate processing apparatus 200d of FIG. 13. Alternatively, the ring body 310 may be installed in a space between the base 211 and the inner sidewall of the chamber housing CH. FIG. 12 is a first example view illustrating an arrangement of a ring body constituting an internal pressure control apparatus. FIG. 13 is a second example view illustrating an arrangement of a ring body constituting an internal pressure control apparatus.

The ring body 310 may be formed of a material having etch resistance in order to minimize damage or deformation due to radicals or the like in the inner space of the chamber housing CH in which plasma is generated. For example, the ring body 310 may be formed to include quartz.

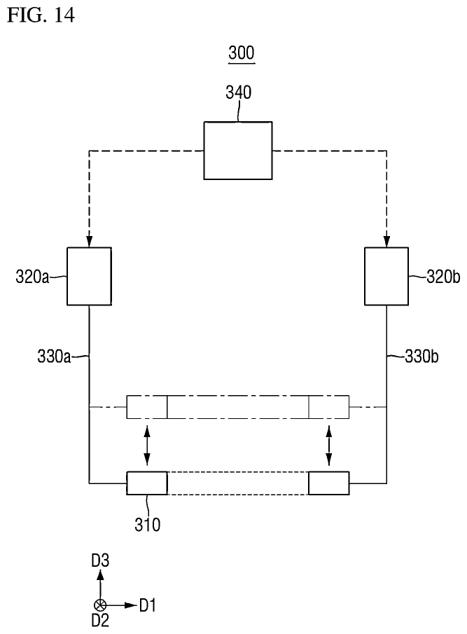

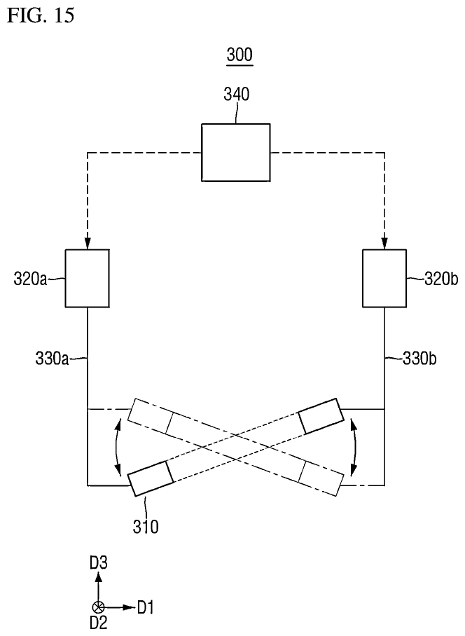

Referring again to FIG. 7, the first driving unit 320a and the second driving unit 320b serve to control movement of the ring body 310. As shown in the example of FIG. 14, the first driving unit 320a and the second driving unit 320b may move the ring body 310 in the vertical direction (the third direction D3), but the present disclosure is not limited thereto. The first driving unit 320a and the second driving unit 320b may tilt the ring body 310 as shown in the example of FIG. 15. The first driving unit 320a and the second driving unit 320b may include a motor to control the movement of the ring body 310, but are not limited thereto. The first driving unit 320a and the second driving unit 320b may include a hydraulic cylinder, a pneumatic cylinder, and the like.

When the first driving unit 320a and the second driving unit 320b control the movement of the ring body 310 as described above, the upper surface of the semiconductor substrate W may be processed uniformly. That is, the problem of chemical non-uniformity in each area, such as the center area, the middle area, and the edge area, may be solved, and the asymmetric problem in each area divided in the east-west and north-south directions may be solved. FIG. 14 is a first example view illustrating a ring body control method of a driving unit constituting an internal pressure control apparatus. FIG. 15 is a second example view illustrating a ring body control method of a driving unit constituting an internal pressure control apparatus.

The first driving unit 320a and the second driving unit 320b may independently control the movement of the ring body 310. The first driving unit 320a and the second driving unit 320b may simultaneously control the movement of the ring body 310. The first driving unit 320a and the second driving unit 320b may control the movement of the ring body 310 at different times. The first driving unit 320a and the second driving unit 320b may equally control the movement of the ring body 310. The first driving unit 320a and the second driving unit 320b may differentially control the movement of the ring body 310. The first driving unit 320a and the second driving unit 320b may locally control the exhaust pressure by independently controlling the ring body 310. That is, the first driving unit 320a and the second driving unit 320b may control the internal pressure of the chamber housing CH for each area by independently controlling the ring body 310. A time varying pressure may be controlled by only individual control of the first driving unit 320a and the second driving unit 320b without change of H/W in the substrate processing apparatus 200, and there is no connection portion so that a singularity does not occur.

The first driving unit 320a and the second driving unit 320b may move the ring body 310 in the vertical direction D3 in accordance with the process time. The first driving unit 320a and the second driving unit 320b may tilt the ring body 310 in accordance with the process time. In this case, the process time refers to the time when the substrate processing apparatus 200 processes the semiconductor substrate W. The internal pressure control apparatus 300 may control the pressure change over time, that is, the time varying pressure, inside the chamber housing CH in accordance with this operation of the ring body 310.

Both the movement of the ring body 310 in the vertical direction D3 and the tilting of the ring body 310 may be performed during the process time. The movement of the ring body 310 in the vertical direction D3 and the tilting of the ring body 310 may be simultaneously performed. The movement of the ring body 310 in the vertical direction D3 and the tilting of the ring body 310 may be performed with a time difference. Only one of the movement of the ring body 310 in the vertical direction D3 and the tilting of the ring body 310 may be performed during the process time.

When the ring body 310 is tilted in accordance with the process time, the first driving unit 320a and the second driving unit 320b may be continuously driven in a cycle. When the process time includes a first cycle and a second cycle, the first driving unit 320a and the second driving unit 320b may uniformly control the internal pressure of the chamber housing CH during the first cycle. In addition, the first driving unit 320a and the second driving unit 320b may uniformly control the internal pressure of the chamber housing CH during the second cycle.

When the ring body 310 is tilted in accordance with the process time, the first driving unit 320a and the second driving unit 320b may be driven in a step between cycles. When the process time includes the first cycle and the second cycle, the first driving unit 320a and the second driving unit 320b may change and control the internal pressure of the chamber housing CH between the first cycle and the second cycle.

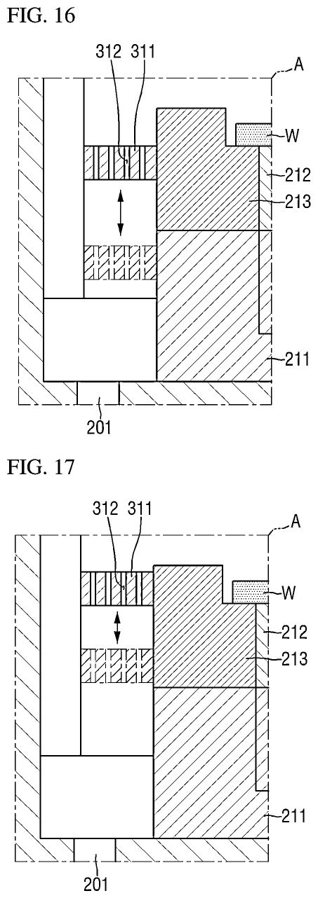

When the first driving unit 320a and the second driving unit 320b move the ring body 310 in the vertical direction D3, the ring body 310 may reciprocate the space between the electro static chuck 212 and the liner unit 260 and the space between the base 211 and the liner unit 260, as shown in the example of FIG. 16, but is not limited thereto. As shown in the example of FIG. 17, the ring body 310 may reciprocate a space between an upper end of the ring assembly 213 and the liner unit 260 and a space between a lower end of the ring assembly 213 and the liner unit 260. FIG. 16 is a first example view illustrating a movement change of a ring body under the control of a driving unit. FIG. 17 is a second example view illustrating a movement change of a ring body under the control of a driving unit.

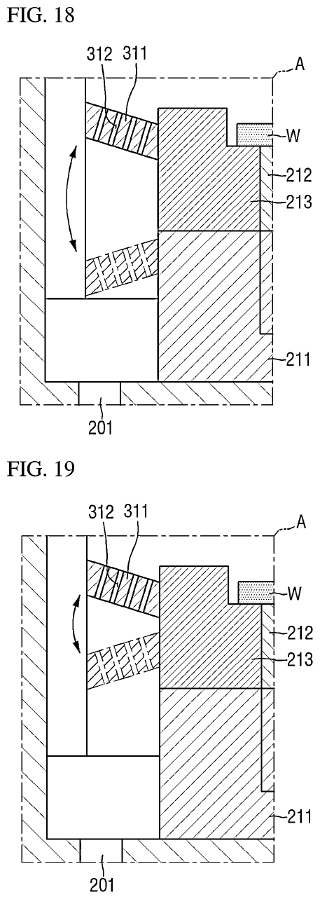

When the first driving unit 320a and the second driving unit 320b tilt the ring body 310, the ring body 310 may be tilted in the space between the base 211 and the liner unit 260 and the space between the electro static chuck 212 and the liner unit 260, as shown in the example of FIG. 18, but is not limited thereto. As shown in the example of FIG. 19, the ring body 310 may be tilted in the space between the upper end of the ring assembly 213 and the liner unit 260 and the space between the lower end of the ring assembly 213 and the liner unit 260. FIG. 18 is a third example view illustrating a movement change of a ring body under the control of a driving unit. FIG. 19 is a fourth example view illustrating a movement change of a ring body under the control of a driving unit.

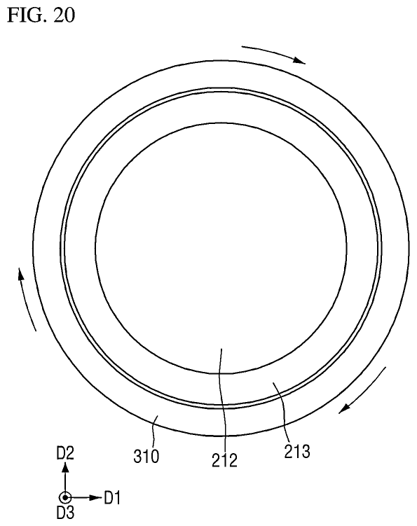

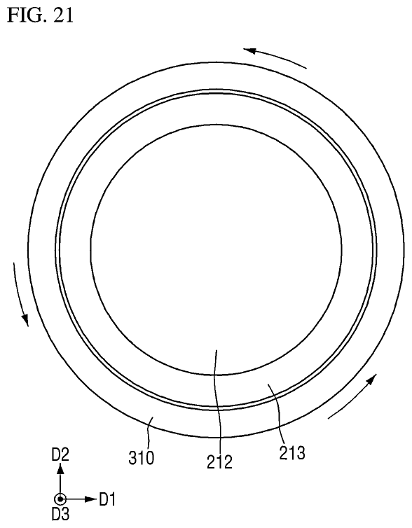

The first driving unit 320a and the second driving unit 320b may rotate the ring body 310 along the periphery of the substrate support unit 210. The ring body 310 may rotate clockwise as shown in the example of FIG. 20, but is not limited thereto. The ring body 310 may rotate counterclockwise as shown in the example of FIG. 21. FIG. 20 is a third example view illustrating a ring body control method of a driving unit constituting an internal pressure control apparatus. FIG. 21 is a fourth example view illustrating a ring body control method of a driving unit constituting an internal pressure control apparatus.

The first driving unit 320a and the second driving unit 320b may rotate the ring body 310 in accordance with a distance. That is, the first driving unit 320a and the second driving unit 320b may move the ring body 310 as much as a predetermined distance by rotating the ring body 310 and stop the ring body 310 at the position where the ring body 310 moves, but are not limited thereto. The first driving unit 320a and the second driving unit 320b may rotate the ring body 310 in accordance with time. That is, the first driving unit 320a and the second driving unit 320b may rotate the ring body 310 for a predetermined time and stop the ring body 310 when a corresponding time elapses.

The ring body 310 may control the amount of the process gas in the chamber housing CH while rotating under the control of the first driving unit 320a and the second driving unit 320b. The ring body 310 may control the amount of the process gas by the above-described operation when an error occurs between E/R in the east-west direction and E/R in the south-north direction. The plurality of slot holes 312 formed in the ring body 310 may not be spaced apart from each other at constant intervals. Alternatively, the plurality of slot holes 312 may not have the same diameter/radius.

Referring again to FIG. 7, the first connection member 330a serves to connect the ring body 310 with the first driving unit 320a. The second connection member 330b serves to connect the ring body 310 with the second driving unit 320b. The first driving unit 320a and the second driving unit 320b may convert electric energy into mechanical energy and then transfer the mechanical energy to the ring body 310 through the first connection member 330a and the second connection member 330b to control the movement of the ring body 310.

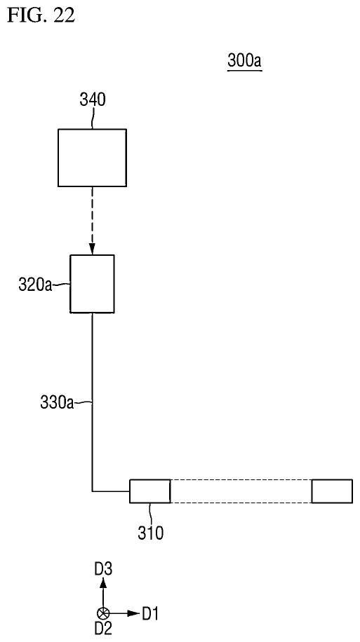

The first driving unit 320a may be disposed to be adjacent to one side of the ring body 310. The second driving unit 320b may be disposed to be adjacent to the other side of the ring body 310. The first driving unit 320a and the second driving unit 320b may be disposed to face each other with the ring body 310 interposed therebetween, but the present disclosure is not limited thereto. The internal pressure control apparatus 300 may include a single driving unit (that is, the first driving unit 320a) and a single connection member (that is, the first connection member 330a) as shown in the example embodiment of the internal pressure control apparatus 300a of FIG. 22. FIG. 22 is a second example view illustrating components of an internal pressure control apparatus applied to a substrate processing apparatus.

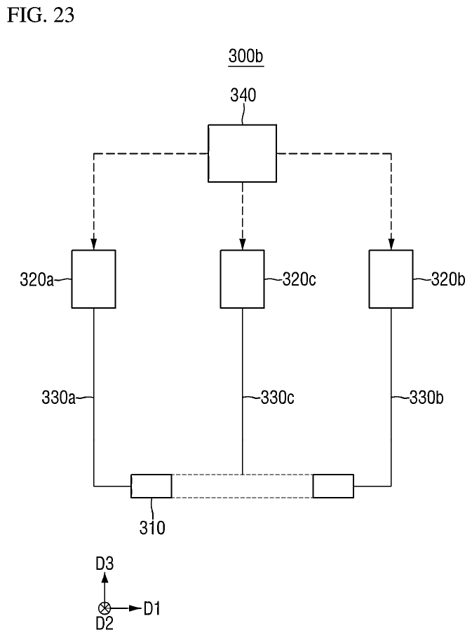

Alternatively, the internal pressure control apparatus 300 may include three or more driving units and connection members. For example, as shown in the example embodiment of FIG. 23, the internal pressure control apparatus 300b may include three driving units 320a, 320b and 320c such as a first driving unit 320a, a second driving unit 320b and a third driving unit 320c, and three connection members 330a, 330b, and 330c such as a first connection member 330a, a second connection member 330b, and a third connection member 330c. When the internal pressure control apparatus 300 includes three or more driving units, the driving units may be disposed at the same interval, but the present disclosure is not necessarily limited thereto. FIG. 23 is a third example view illustrating components of an internal pressure control apparatus applied to a substrate processing apparatus.

Referring again to FIG. 7, the control unit 340 serves to control the operation of the first driving unit 320a and the second driving unit 320b. The first driving unit 320a and the second driving unit 320b may control the movement of the ring body 310 in accordance with the control of the control unit 340.

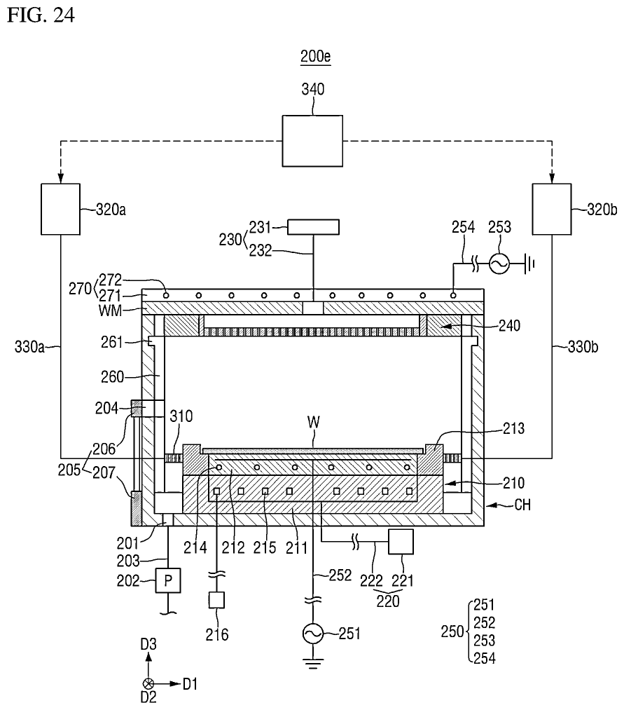

The ring body 310 may be disposed inside the chamber housing CH, but the first driving unit 320a, the second driving unit 320b and the control unit 340 may be disposed outside the chamber housing CH as shown in the example embodiment of the substrate processing apparatus 200e of FIG. 24. The first connection member 330a may pass through the sidewall of the chamber housing CH to connect the ring body 310 with the first driving unit 320a. The second connection member 330b may pass through the sidewall of the chamber housing CH to connect the ring body 310 with the second driving unit 320b. FIG. 24 is an example view illustrating an installation form in a substrate processing apparatus of an internal pressure control apparatus.

The case that a single ring body is applied to the substrate processing apparatus 200 has been described as described above, but the present disclosure is not limited thereto. A plurality of ring bodies may be applied to the substrate processing apparatus 200. Hereinafter, the case that two ring bodies are applied to the substrate processing apparatus 200 will be described as an example.

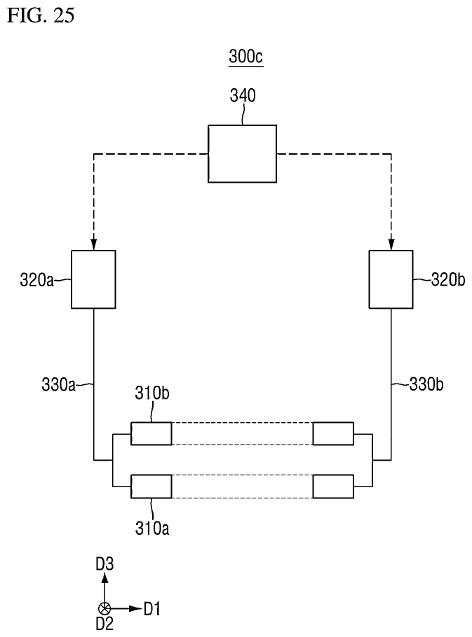

FIG. 25 is a fourth example view illustrating components of an internal pressure control apparatus applied to a substrate processing apparatus. Referring to the example embodiments of FIG. 25, the internal pressure control apparatus 300c may include a first ring body 310a, a second ring body 310b, a first driving unit 320a, a second driving unit 320b, a first connection member 330a, a second connection member 330b, and a control unit 340. Hereinafter, description of a portion duplicated with the case of FIG. 7 will be omitted, and only a portion corresponding to a difference from the case of FIG. 7 will be described.

The first ring body 310a and the second ring body 310b may be disposed to be spaced apart from each other in the vertical direction (the third direction D3). The movement of the first ring body 310a may be controlled by the first driving unit 320a and the second driving unit 320b. The movement of the second ring body 310b may be controlled by the first driving unit 320a and the second driving unit 320b. The first ring body 310a and the second ring body 310b may have the same movement under the control of the first driving unit 320a and the second driving unit 320b. For example, both the first ring body 310a and the second ring body 310b may move in the vertical direction D3. Alternatively, both the first ring body 310a and the second ring body 310b may be tilted.

However, the present disclosure is not limited to the above example, and the first ring body 310a and the second ring body 310b may have their respective movement under the control of the first driving unit 320a and the second driving unit 320b. For example, any one of the first ring body 310a and the second ring body 310b may move in the vertical direction D3, and the other ring body may be tilted. The movement of the first ring body 310a and the second ring body 310b may be controlled within the range that the first ring body 310a and the second ring body 310b do not collide with each other.

The plurality of slot holes 312 formed in the first ring body 310a may have a shape the same as or similar to that of the plurality of slot holes 312 formed in the second ring body 310b. For example, the plurality of slot holes 312 formed in the first ring body 310a and the plurality of slot holes 312 formed in the second ring body 310b may be formed in the vertical direction D3 with respect to the longitudinal direction D1 of the body 311. For example, the plurality of slot holes 312 formed in the first ring body 310a and the plurality of slot holes 312 formed in the second ring body 310b may be all formed in a direction inclined with respect to the longitudinal direction D1 of the body 311. For example, the plurality of slot holes 312 formed in the first ring body 310a and the plurality of slot holes 312 formed in the second ring body 310b may be spaced apart from each other at constant intervals. For example, the plurality of slot holes 312 formed in the first ring body 310a and the plurality of slot holes 312 formed in the second ring body 310b may be spaced apart from each other at different intervals. For example, the plurality of slot holes 312 formed in the first ring body 310a and the plurality of slot holes 312 formed in the second ring body 310b may have the same diameter/radius. For example, the plurality of slot holes 312 formed in the first ring body 310a and the plurality of slot holes 312 formed in the second ring body 310b may have different diameters/radiuses.

However, the present disclosure is not limited to the above example, and the plurality of slot holes 312 formed in the first ring body 310a may have a shape different from that of the plurality of slot holes 312 formed in the second ring body 310b. For example, the slot holes 312 corresponding to any one side of the plurality of slot holes 312 formed in the first ring body 310a and the plurality of slot holes 312 formed in the second ring body 310b may be formed in the vertical direction D3 with respect to the longitudinal direction D1 of the body 311, and the other slot holes 312 may be formed in the direction inclined with respect to the longitudinal direction D1 of the body 311. For example, the slot holes 312 corresponding to any one side of the plurality of slot holes 312 formed in the first ring body 310a and the plurality of slot holes 312 formed in the second ring body 310b may be spaced apart from each other at a predetermined interval, and the other slot holes 312 may be spaced apart from each other at different intervals. For example, the slot holes 312 corresponding to any one side of the plurality of slot holes 312 formed in the first ring body 310a and the plurality of slot holes 312 formed in the second ring body 310b may have the same diameter/radius, and the other slot holes 312 may have different diameters/radiuses.

The first ring body 310a and the second ring body 310b may have the same movement in relation to rotational movement. For example, both the first ring body 310a and the second ring body 310b may rotate clockwise. For example, both the first ring body 310a and the second ring body 310b may rotate counterclockwise. For example, both the first ring body 310a and the second ring body 310b may rotate in accordance with a distance. Both the first ring body 310a and the second ring body 310b may rotate in accordance with time.

However, the present disclosure is not limited to the above example, and the first ring body 310a and the second ring body 310b may have their respective movement in relation to rotational movement. For example, any one of the first ring body 310a and the second ring body 310b may rotate, and the other ring body may not rotate. For example, any one of the first ring body 310a and the second ring body 310b may rotate clockwise, and the other ring body may rotate counterclockwise. For example, any one of the first ring body 310a and the second ring body 310b may rotate in accordance with a distance, and the other ring body may rotate in accordance with time.

The first driving unit 320a and the second driving unit 320b may control the movement of the first ring body 310a and the second ring body 310b under the control of the control unit 340. The first driving unit 320a and the second driving unit 320b may simultaneously control the first ring body 310a and the second ring body 310b. For example, when the first ring body 310a and the second ring body 310b have the same movement, the first driving unit 320a and the second driving unit 320b may simultaneously control the first ring body 310a and the second ring body 310b.

However, the present disclosure is not limited to the above example, and the first driving unit 320a and the second driving unit 320b may individually control the first ring body 310a and the second ring body 310b. For example, when the first ring body 310a and the second ring body 310b have their respective movement, the first driving unit 320a and the second driving unit 320b may individually control the first ring body 310a and the second ring body 310b.

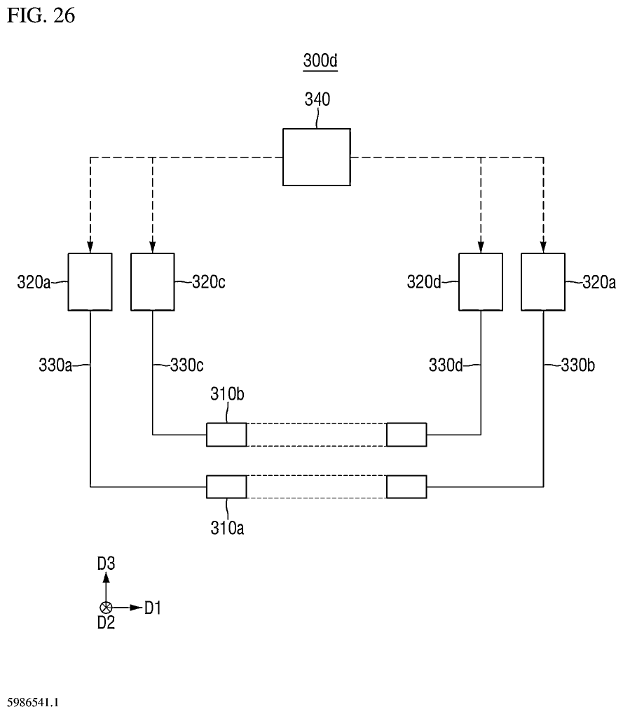

Meanwhile, the internal pressure control apparatus 300 may separately include a driving unit for controlling each ring body. The driving units may individually control each ring body. In some example embodiments, when the internal pressure control apparatus 300d includes a first ring body 310a and a second ring body 310b, as shown in FIG. 26, the internal pressure control apparatus 300d may include first and second driving units 320a and 320b for controlling the movement of the first ring body 310a, and third and fourth driving units 320c and 320d for controlling the movement of the second ring body 310b. FIG. 26 is a fifth example view illustrating components of an internal pressure control apparatus applied to a substrate processing apparatus.

In the present disclosure, the internal pressure control apparatus 300, the substrate processing apparatus 200 that serves to process the semiconductor substrate W and includes the internal pressure control apparatus 300, and the semiconductor manufacturing facility 100 that includes the substrate processing apparatus 200 have been described as above. The internal pressure control apparatus 300 may include a ring body 310 that serves as a pressure control ring. The internal pressure control apparatus 300 may uniformly process the upper surface of the semiconductor substrate W in the substrate processing apparatus 200 by controlling a posture of the ring body 310. In addition, the internal pressure control apparatus 300 may improve chemical uniformity, and may improve E/R uniformity. In addition, the internal pressure control apparatus 300 may improve mean velocity uniformity, and may improve a defect due to airflow.

The internal pressure control apparatus 300 may control the posture of the ring body 310 by moving the ring body 310 in the vertical direction. The internal pressure control apparatus 300 may control the posture of the ring body 310 by tilting the ring body 310. That is, the internal pressure control apparatus 300 may control the time varying pressure through the vertical movement of the ring body 310 and/or the tilting of the ring body 310. In addition, the internal pressure control apparatus 300 may have a structure that is averaged over a flow rate time so that the upper surface of the semiconductor substrate W is uniformly processed.

According to the present disclosure, velocity distribution of the process gas on the upper surface of the semiconductor substrate W may be improved. An airflow above the semiconductor substrate W may be separated into components such as a flow magnitude and a flow angle to identify its characteristics. For chemical uniformity, the velocity distribution should be uniform in the entire area of the substrate, and a larger incident angle relative to the surface of the substrate is better in terms of the discharge of the by-products.

When the posture of the ring body 310 is controlled as in the present disclosure, for example, when a time varying tilting motion for the ring body 310 is used, the velocity distribution of the airflow in the entire area of the semiconductor substrate W may be reduced. In the conventional case, the velocity distribution on the upper surface of the semiconductor substrate W has a low-velocity period formed in the center area and a high-velocity period formed in the outer area. According to the present disclosure, the low-velocity period is transferred to the outside through asymmetric flow generated by the tilting of the ring body 310, and a time-averaged distribution of a flow rate may be improved through the time varying tilting control of the ring body 310. A velocity difference between the center area and the outer area may be improved, for example, by up to 50%, through the time varying tilting control without change of H/W in the substrate processing apparatus 200.

According to the present disclosure, an airflow incident angle may be improved on the upper surface of a semiconductor substrate W. When the time varying tilting motion is applied, an airflow incident angle with respect to the upper surface of the substrate may be improved. When the incident angle with respect to the surface of the substrate is small, by-products may be easily stacked on an etched portion, and the larger incident angle is better in terms of the discharge of the by-products.

The airflow angle distribution is similar to the velocity distribution. In the conventional case, a low incident angle (0° to 80°) is formed in the center area, and a high incident angle (80° to 90°) is formed in the outer area. According to the present disclosure, a low angle area may be transferred to the outside through asymmetric flow generated by the tilting of the ring body 310, and the time-averaged distribution of the flow rate may be improved through the time varying tilting control of the ring body 310. The average angle may be improved, for example, up to 80° or more, through the time varying tilting control without change of H/W in the substrate processing apparatus 200.

According to the present disclosure, the distribution of the airflow velocity in the east-west direction may be improved on the upper surface of the semiconductor substrate W. Among many etching processes for generating a pattern of the semiconductor substrate W, a specific process (for example, a word line cut (WLC) process) has a long pattern generated in one direction. In this process, there is a large difference in the E/R in east-west/south-north positions due to the airflow in the pattern direction (cut direction), whereby many defects are caused in the semiconductor substrate W.

When the present disclosure is applied, the time-averaged distribution of the flow rate in the east-west direction may be improved through the time varying tilting control. The time-averaged velocity may be improved through the time varying tilting control without change of H/W in the substrate processing apparatus 200.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

Example embodiments of the present disclosure have been described hereinabove with reference to the accompanying drawings, but the present disclosure is not limited to the above-described example embodiments, and may be implemented in various different forms, and one of ordinary skill in the art to which the present disclosure pertains may understand that the present disclosure may be implemented in other specific forms without changing the technical concept or features of the present disclosure. Therefore, it is to be understood that the example embodiments described above are illustrative rather than being restrictive in all aspects.

What is claimed is:

1. A substrate processing apparatus comprising:
a chamber housing including an exhaust hole configured to exhaust a process gas flowing thereinto;
a substrate support unit inside the chamber housing, the substrate support unit configured to support a semiconductor substrate;
a process gas supply unit configured to provide the process gas to the inside of the chamber housing;
a plasma generating unit configured to generate plasma inside the chamber housing by using the process gas; and
an internal pressure control apparatus configured to control an internal pressure of the chamber housing, the internal pressure control apparatus including a ring body around the substrate support unit and provided as one body, the internal pressure control apparatus being configured to control a posture of the ring body such that an exhaust amount of the process gas flowing into the chamber housing is controlled.

2. The substrate processing apparatus of claim 1, wherein the internal pressure control apparatus is configured to control the posture of the ring body by tilting the ring body.

3. The substrate processing apparatus of claim 1, wherein the internal pressure control apparatus is configured to control the posture of the ring body by moving the ring body along a height direction of the substrate support unit.

4. The substrate processing apparatus of claim 1, wherein the internal pressure control apparatus controls the internal pressure of the chamber housing for each area.

5. The substrate processing apparatus of claim 1, wherein the internal pressure control apparatus is configured to control the internal pressure of the chamber housing in accordance with a process time for the semiconductor substrate.

6. The substrate processing apparatus of claim 5, wherein the process time includes a plurality of cycles, and
the internal pressure control apparatus is configured to uniformly control the internal pressure of the chamber housing for each cycle.

7. The substrate processing apparatus of claim 5, wherein the process time includes a plurality of cycles, and
the internal pressure control apparatus is configured to control the internal pressure of the chamber housing by changing the internal pressure of the chamber housing between two different cycles.

8. The substrate processing apparatus of claim 1, wherein the internal pressure control apparatus further includes:
a first driving unit connected to one side of the ring body through a first connection member; and
a second driving unit connected to the other side of the ring body through a second connection member, and
the first driving unit and the second driving unit are each configured to the posture of the ring body.

9. The substrate processing apparatus of claim 8, wherein the first driving unit and the second driving unit are configured to independently control the ring body.

10. The substrate processing apparatus of claim 8, wherein the internal pressure control apparatus further includes a third driving unit connected to the ring body through a third connection member, and
the third driving unit is connected to another side except the one side and the other side.

11. The substrate processing apparatus of claim 1, wherein the substrate processing apparatus is configured to uniformly process an upper surface of the semiconductor substrate in accordance with an operation of the internal pressure control apparatus.

12. The substrate processing apparatus of claim 1, wherein the internal pressure control apparatus includes a plurality of ring bodies, each of which is spaced apart from another one in a height direction of the substrate support unit.

13. The substrate processing apparatus of claim 1, wherein the substrate processing apparatus is a facility configured to etch the semiconductor substrate.

14. The substrate processing apparatus of claim 1, wherein the ring body is on a path through which the process gas flowing into the chamber housing moves to the exhaust hole.

15. A substrate processing apparatus comprising:
a chamber housing including an exhaust hole configured to exhaust a process gas flowing thereinto;
a substrate support unit inside the chamber housing, the substrate support unit configured to support a semiconductor substrate;
a process gas supply unit configured to provide the process gas to the inside of the chamber housing;
a plasma generating unit configured to generate plasma inside the chamber housing by using the process gas; and
an internal pressure control apparatus inside the chamber housing, the internal pressure control apparatus comprising:
a ring body installed around a substrate support unit, the substrate support unit configured to support the semiconductor substrate, and the ring body provided as one body;
a first driving unit connected to one side of the ring body through a first connection member; and
a second driving unit connected to the other side of the ring body through a second connection member,
the internal pressure control apparatus being configured to control a pressure of a space, in which the semiconductor substrate is processed, based on controlling a posture of the ring body.

16. The substrate processing apparatus of claim 15, wherein the internal pressure control apparatus is configured to control an exhaust amount of a process gas flowing into the space in which the semiconductor substrate is processed.

17. The substrate processing apparatus of claim 15, wherein the first driving unit and the second driving unit are configured to control the posture of the ring body by tilting the ring body.

18. The substrate processing apparatus of claim 15, wherein the first driving unit and the second driving unit are configured to independently control the ring body.

19. The substrate processing apparatus of claim 15, wherein the first driving unit and the second driving unit are configured to control the posture of the ring body by moving the ring body along a height direction of the substrate support unit.

20. A substrate processing apparatus comprising:
a chamber housing including an exhaust hole configured to exhaust a process gas flowing thereinto;
a substrate support unit inside the chamber housing, configured to support a semiconductor substrate;
a process gas supply unit configured to provide the process gas to the inside of the chamber housing;
a plasma generating unit configured to generate plasma inside the chamber housing by using the process gas; and
an internal pressure control apparatus configured to control an internal pressure of the chamber housing,
the internal pressure control apparatus including
a ring body around the substrate support unit and provided as one body;
a first driving unit connected to one side of the ring body through a first connection member; and
a second driving unit connected to the other side of the ring body through a second connection member, and
the internal pressure control apparatus configured to control a posture of the ring body by tilting the ring body and control an exhaust amount of a process gas flowing into the chamber housing,
the internal pressure control apparatus configured to control the internal pressure of the chamber housing in accordance with a process time for the semiconductor substrate, the process time including a plurality of cycles, uniformly controls the internal pressure of the chamber housing for each cycle, and controls the internal pressure of the chamber housing by changing the internal pressure of the chamber housing between two different cycles, and
the first driving unit and the second driving unit independently control the ring body.
